(19) United States
(12) Patent Application Publication
(10) Pub. No.: US 2026/0025130 A1
(43) Pub. Date: Jan. 22, 2026

(54) SWITCH CONTROL CIRCUIT AND RADIO FREQUENCY SWITCH CIRCUIT

(71) Applicant: Samsung Electro-Mechanics Co., Ltd., Suwon-si (KR)

(72) Inventors: Shinhaeng HEO, Suwon-si (KR); Byeonghak JO, Suwon-si (KR); Wonsun HWANG, Suwon-si (KR); Byungjoo HONG, Suwon-si (KR); Dongil KANG, Suwon-si (KR)

(73) Assignee: Samsung Electro-Mechanics Co., Ltd., Suwon-si (KR)

(21) Appl. No.: 18/895,875

(22) Filed: Sep. 25, 2024

(30) Foreign Application Priority Data
Jul. 17, 2024 (KR) 10-2024-0094651

(51) Int. Cl. H03K 17/06; H02M 3/07

(52) U.S. Cl. CPC H03K 17/063; H02M 3/07

(57) ABSTRACT

A switch control circuit that controls a first switch connected between a first port and a second port, and switches a radio frequency (RF) signal, is provided. The switch control circuit includes a first charge pump circuit configured to generate, in a first mode, a first negative voltage based on a first voltage; a second charge pump circuit configured to generate, in a second mode, a second negative voltage higher than the first negative voltage based on a second voltage; and a first switch driver configured to turn off, in the second mode, the first switch by providing the second negative voltage to a control terminal of the first switch.

### CROSS-REFERENCE TO RELATED APPLICATIONS

This application claims the benefit under 35 USC § 119(a) of Korean Patent Application No. 10-2024-0094651 filed on Jul. 17, 2024, in the Korean Intellectual Property Office, the entire disclosure of which is incorporated herein by reference for all purposes.

### BACKGROUND

### 1. Field

This following description relates to switch control circuits and radio frequency switch circuits.

### 2. Description of Related Art

In communication modules, a radio frequency (RF) switch circuit may include a series switch that passes or blocks a signal between a signal port and an antenna port, and a shunt switch that passes the signal between the signal port and the antenna port to ground. The series switch and the shunt switch may be turned on or off depending on a voltage output from a switch control circuit. A power supply voltage may be used as a turn-on voltage of the series switch and the shunt switch, and a negative voltage may be used as a turn-off voltage of the series switch and shunt switch.

It is desirable that the RF switch circuit have specifications of −40 dBm in an active mode as radiated spurious emissions (RSE) performance is strengthened, and it is desirable that the RF switch circuit have the same level of RSE performance in a low power mode as in the active mode.

The RSE performance in the active mode may be satisfactory depending on the implementation of the shunt switch. On the other hand, in the low power mode, the elements that supply the power supply voltage and negative voltage are turned off, so the series switch and the shunt switch may not operate with the power supply voltage or negative voltage.

Accordingly, in the low power mode, the series switch and shunt switch may be turned off at an unspecified voltage, for example, 0V, and in this case, the harmonic characteristics of the second or higher order at the antenna terminal are not good.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a switch control circuit that controls a first switch connected between a first port and a second port, and switches a radio frequency (RF) signal includes a first charge pump circuit configured to generate, in a first mode, a first negative voltage based on a first voltage; a second charge pump circuit configured to generate, in a second mode, a second negative voltage higher than the first negative voltage based on a second voltage; and a first switch driver configured to turn off the first switch in the second mode by providing the second negative voltage to a control terminal of the first switch.

The switch control circuit may further include a second switch driver configured to turn on a second switch connected between the second port and ground by providing the second voltage to a control terminal of the second switch in the second mode.

The switch control circuit may further include a third switch driver configured to turn on a third switch connected between the second port and the ground by providing the second voltage to a control terminal of the third switch in the second mode.

The switch control circuit may further include a charge pump selection switch configured to provide the first negative voltage to the first switch driver, the second switch driver, and third switch driver in the first mode, and configured to provide the second negative voltage to the first driver and the third switch driver in the second mode.

The first switch driver may be configured to turn on the first switch by providing the first voltage to the control terminal of the first switch in the first mode, the second switch driver may be configured to turn off the second switch by providing the first negative voltage to the control terminal of the second switch in the first mode, and the third switch driver may be configured to turn off the third switch by providing the first negative voltage to the control terminal of the third switch in the first mode.

The switch control circuit may further include a power source selection switch configured to provide the first voltage to the first switch driver and the second switch driver in the first mode, and configured to provide the second voltage to the second switch driver in the second mode.

The switch control circuit may further include a charge pump selection switch configured to provide the first negative voltage to the first switch driver, the second switch driver, and the third switch driver in the first mode, and configured to provide the second negative voltage to the first switch driver in the second mode.

The first mode may be an active mode that transmits or receives the RF signal, and the second mode is a low power mode that minimizes power consumption.

The active mode may include at least one of a transmission mode, a reception mode, and a transmission and reception mode, and the first switch driver may be configured to turn on the first switch by providing the first voltage to the control terminal of the first switch, and is configured to turn off the first switch by providing the first negative voltage to the control terminal of the first switch, in the at least one of the transmission mode, the reception mode, and the transmission and reception mode.

In a general aspect, a radio frequency (RF) switch circuit includes a first switch connected between a first port and an antenna port; a second switch connected between the antenna port and ground; and a switch control circuit configured to control the first switch and the second switch, wherein the switch control includes a first charge pump circuit configured to generate, in a first mode, a first negative voltage based on a first voltage; a second charge pump circuit configured to generate, in a second mode, a second negative voltage higher than the first negative voltage based on a second voltage; and a first switch driver configured to provide the first negative voltage as a turn-off voltage of the first switch in the first mode, and provide the second negative voltage as a turn-off voltage of the first switch in the second mode.

The RF switch circuit may include a third switch connected between the antenna port and the ground, and configured to be turned off in the first mode and turned on in the second mode; and a third switch driver configured to provide the first negative voltage as a turn-off voltage of the third switch in the first mode, and provide the second voltage as a turn-on voltage of the third switch in the second mode.

The RF switch circuit may include a second switch driver configured to provide the first negative voltage as a turn-off voltage of the second switch in the first mode, and provide the second voltage as a turn-on voltage of the second switch in the second mode.

The RF switch circuit may include a power source selection switch configured to provide the first voltage to the first switch driver and the second switch driver in the first mode, and configured to provide the second voltage to the second switch driver in the second mode.

The RF switch circuit may include a charge pump selection switch configured to provide the first negative voltage to the first switch driver, the second switch driver, and the third switch driver in the first mode, and configured to provide the second negative voltage to the first switch driver and the third switch driver in the second mode.

The RF switch circuit may include a second switch driver configured to provide the first negative voltage as a turn-off voltage of the second switch in the first mode, and float the control terminal of the second switch in the second mode.

The first mode may be an active mode that transmits or receives an RF signal through the first switch, and the second mode is a low power mode that minimizes power consumption.

Other features and aspects will be apparent from the following detailed description, the drawings, and the claims.

### BRIEF DESCRIPTION OF DRAWINGS

FIG. 1 illustrates an example RF switch circuit, in accordance with one or more embodiments.

FIG. 2 illustrates an example general switch control circuit, in accordance with one or more embodiments.

FIG. 3 illustrates an example switch control circuit, in accordance with one or more embodiments.

FIG. 4 illustrates an example charge pump selection switch shown in FIG. 3.

FIG. 5 illustrates another example of the charge pump selection switch shown in FIG. 3.

FIG. 6 and FIG. 7 illustrate an operation of the charge pump selection switch shown in FIG. 5 in active mode and low power mode, respectively.

FIG. 8 illustrates an example RF switch circuit, in accordance with one or more embodiments.

FIG. 9 illustrates an example of the switch control circuit shown in FIG. 8.

FIG. 10 illustrates another example of the switch control circuit shown in FIG. 8.

FIG. 11 illustrates an example of the power selection switch shown in FIG. 10.

FIG. 12, FIG. 13, and FIG. 14 illustrate simulation results of the first to sixth harmonics according to the positive and negative voltages applied to the RF switch circuit, respectively.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide a switch control circuit and an RF switch circuit that can improve harmonic characteristics of an antenna terminal in a low power mode.

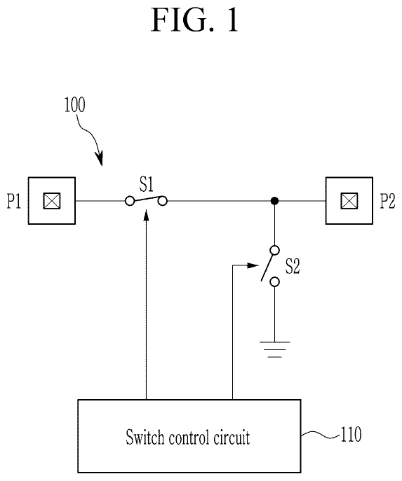

FIG. 1 illustrates an example RF switch circuit, in accordance with one or more embodiments.

Referring to FIG. 1, the RF switch circuit 100 may include a first port P1, a second port P2, a first switch S1, and a second switch S2. The RF switch circuit 100 may further include a switch control circuit 110.

The first switch S1 and the second switch S2 may be implemented with various transistors such as a heterojunction bipolar transistor (HBT), a bipolar junction transistor (BJT), and an insulated gate bipolar transistor (IGBT). The first switch S1 and the second switch S2 may have a first terminal, a second terminal, and a control terminal, respectively. The ‘control terminal’ may be, for example, a gate of a transistor, or a base of a transistor. The first terminal and the second terminal may be the collector or emitter of the transistor.

In an example, the first port P1 may be a transmission port. In an example, the first port P1 may be a reception port.

In an example, the second port P2 may be an antenna port.

When the first port P1 is a transmission port, a path between the first port P1 and the second port P2 may be a transmission path. When the first port P1 is a reception port, a path between the first port P1 and the second port P2 may be a reception path.

The first switch S1 may be connected between the first port P1 and the second port P2.

The second switch S2 may be connected between the second port P2 and ground.

The first switch S1 and the second switch S2 may operate complementary. When the first switch S1 is turned on, the second switch S2 may be turned off, and when the first switch S1 is turned off, the second switch S2 may be turned on.

The switch control circuit 110 may supply a positive voltage to the control terminal of the first switch S1 and the control terminal of the second switch S2, and the first switch S1 and the second switch S2 may be turned on in response to the positive voltage. The switch control circuit 110 may supply a negative voltage to the control terminal of the first switch S1 and the control terminal of the second switch S2, and the first switch S1 and the second switch S2 may be turned off in response to the negative voltage.

The switch control circuit 110 may control on and off operations of the first switch S1 and the second switch S2 according to an operation mode of the RF switch circuit 100. The operating mode of the RF switch circuit 100 may include an active mode and a low power mode. The active mode may mean a mode in which RF signals may be transmitted or received, and the RF switch circuit 100 may be activated. The active mode may include at least one of a transmission mode, a reception mode, and a transmission and reception mode. The low power mode may mean a mode for minimizing current consumption of the RF switch circuit 100.

The switch control circuit 110 may supply the positive voltage to the control terminal of the first switch S1 and the negative voltage to the control terminal of the second switch S2 in the active mode.

In an example, the switch control circuit 110 may supply the negative voltage to the control terminal of the first switch S1 and the control terminal of the second switch S2 in the low power mode.

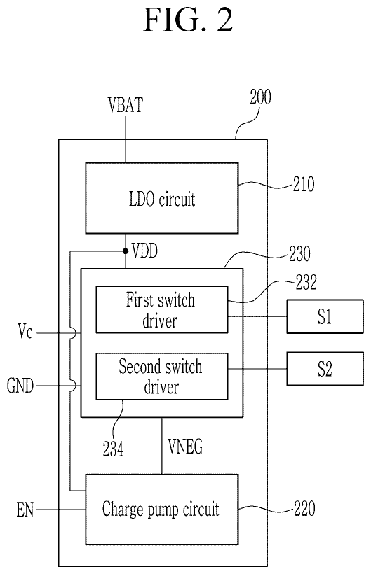

FIG. 2 illustrates an example general switch control circuit, in accordance with one or more embodiments.

Referring to FIG. 2, the switch control circuit 200 may include a low dropout (LDO) circuit 210, a charge pump circuit 220, and a buffer control circuit 230.

The LDO circuit 210 may generate a positive voltage VDD lower than the battery voltage VBAT from the battery voltage VBAT supplied from the battery power source, and provide the positive voltage VDD to the buffer control circuit 230. Additionally, the LDO circuit 210 may provide the positive voltage VDD to the charge pump circuit 220.

The charge pump circuit 220 may generate a negative voltage VNEG by charge pumping the positive voltage VDD according to the enable signal EN, and provide the negative voltage VNEG to the buffer control circuit 230.

The buffer control circuit 230 may include a first switch driver 232 and a second switch driver 234.

The first switch driver 232 may generate a first switch control signal in response to the control signal Vc, and provide the first switch control signal to the control terminal of the first switch S1.

The second switch driver 234 may generate a second switch control signal in response to the control signal Vc, and provide the second switch control signal to the control terminal of the second switch S2.

The first switch driver 232 may provide the voltage VDD as the first switch control signal to the control terminal of the first switch S1 in the active mode, and the second switch driver 234 may provide the negative voltage VNEG as a second switch control signal to the control terminal of the second switch S2 in the active mode.

In an example, in the low power mode, the LDO circuit 210 and the charge pump circuit 220 may be turned off. The first switch driver 232 and the second switch driver 234 cannot receive the negative voltage VNEG from the charge pump circuit 220 in the low power mode, and cannot provide any voltage to the control terminal of the first switch S1 and the control terminal of the second switch S2. Accordingly, the control terminal of the first switch S1 and the control terminal of the second switch S2 are in a floating state, and the voltages of the control terminal of the first switch S1 and the control terminal of the second switch S2 have an undefined voltage value, not negative voltage VNEG. At this time, the voltages of the control terminal of the first switch S1 and the control terminal of the second switch S2 may be 0V, and the first switch S1 and the second switch S2 may be turned off.

However, in the low power mode, when the voltages of the control terminal of the first switch S1 and the control terminal of the second switch S2 become 0V and the first switch S1 and the second switch S2 operate in an off state, the harmonic characteristics of the second or higher order at the antenna terminal deteriorate.

According to an embodiment, a charge pump circuit that operates only in the low power mode can be used to improve the harmonic characteristics at the antenna stage in the low power mode.

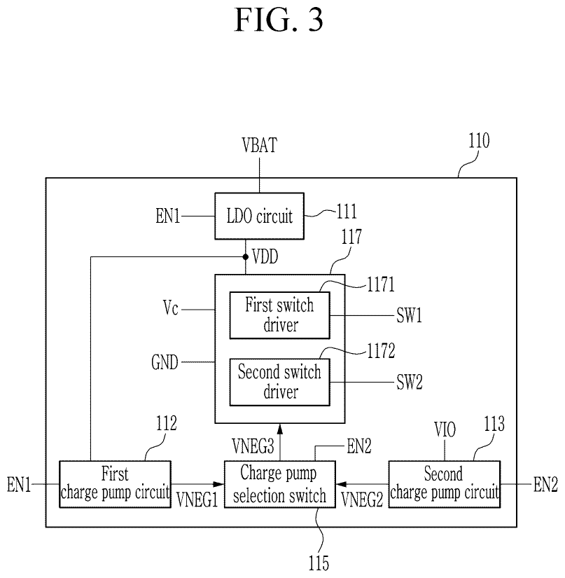

FIG. 3 illustrates an example switch control circuit, in accordance with one or more embodiments.

Referring to FIG. 3, the switch control circuit 110 may include an LDO circuit 111, a first charge pump circuit 112, a second charge pump circuit 113, a charge pump selection switch 115, and a buffer control circuit 117.

The LDO circuit 111 may be activated in response to a first enable signal EN1, may generate a positive voltage VDD from a battery voltage VBAT, and may provide the positive voltage VDD to the first charge pump circuit 112 and the buffer control circuit 117.

The first charge pump circuit 112 may be activated in response to the first enable signal EN1 and may generate a negative voltage VNEG1 by charge pumping the positive voltage VDD.

The second charge pump circuit 113 may be activated in response to a second enable signal EN2 and may generate a negative voltage VNEG2 by charge pumping a positive voltage VIO. The positive voltage VIO is a voltage supplied from a constant power source different from the battery voltage VBAT and may be lower than the positive voltage VDD.

At this time, the first enable signal EN1 and the second enable signal EN2 may have a first level and a second level. In an example, the first level may be a high level and the second level may be a low level. Alternatively, the first level may be a low level and the second level may be a high level. The first enable signal EN1 and the second enable signal EN2 may have a complementary relationship.

According to an embodiment, in the active mode, the first enable signal EN1 may be set to the first level and the second enable signal EN2 may be set to the second level. In the low power mode, the first enable signal EN1 may be set to the second level and the second enable signal EN2 may be set to the first level.

Below, it is explained that the first level is a high level and the second level is a low level.

The LDO circuit 111 is activated (on) in response to the high level of the first enable signal EN1, and may generate the positive voltage VDD in the activated state. In an example, the LDO circuit 111 may be in a deactivated (off) state in response to the low level of the first enable signal EN1.

The first charge pump circuit 112 is activated in response to the high level of the first enable signal EN1, and may generate the negative voltage VNEG1 in the activated state. At this time, the second charge pump circuit 113 may be in a deactivated (off) state in response to the low level of the second enable signal EN2.

The first charge pump circuit 112 may be in the deactivated (off) state in response to the low level of the first enable signal EN1. At this time, the second charge pump circuit 113 may be in an activated (on) state in response to the high level of the second enable signal EN2, and may generate the negative voltage VNEG2 in the activated state.

According to an embodiment, the positive voltage VIO may be lower than the positive voltage VDD. Accordingly, the negative voltage VNEG2 may be a higher voltage than the negative voltage VNEG1.

In an example, when the positive voltage VDD is 2.5V, and the positive voltage VIO is 1.8V, the first charge pump circuit 112 may generate a voltage of −2.3V by charge pumping a voltage of 2.5V, and the second charge pump circuit 113 may generate a voltage of −1.8V by charge pumping a voltage of 1.8V.

The charge pump selection switch 115 may provide a negative voltage VNEG3 to the buffer control circuit 117 based on the second enable signal EN2. The charge pump selection switch 115 may provide the negative voltage VNEG1 generated in the first charge pump circuit 112 or the negative voltage VNEG2 generated in the second charge pump circuit 113 as the negative voltage VNEG3, based on the second enable signal EN2.

According to the embodiment, when the second enable signal EN2 is at the low level, the operation mode of the RF switch circuit 100 indicates the active mode, so the charge pump selection switch 115 may provide the negative voltage VNEG1 to the buffer control circuit 117 as the negative voltage VNEG3 corresponding to the active mode.

In an example, when the second enable signal EN2 is at a high level, the operation mode of the RF switch circuit 100 indicates the low power mode, so the charge pump selection switch 115 may provide the negative voltage VNEG2 to the buffer control circuit 117 as the negative voltage VNEG3 corresponding to the low power mode.

In this way, since the negative voltage VNEG2 may be provided in the low power mode through the second charge pump circuit 113, power consumption may be reduced compared to providing a negative voltage VNEG1 through the first charge pump circuit 112 in the low power mode.

The buffer control circuit 117 may include a first switch driver 1171 and a second switch driver 1172.

The first switch driver 1171 may generate a first switch control signal SW1 in response to the control signal Vc, and provide the first switch control signal SW1 to the control terminal of the first switch S1.

The second switch driver 1172 may generate a second switch control signal SW2 in response to the control signal Vc, and provide the second switch control signal SW2 to the control terminal of the second switch S2.

The first switch driver 1171 may provide the positive voltage VDD as the first switch control signal SW1 to the control terminal of the first switch S1 in the active mode, and the second switch driver 1172 may provide the negative voltage VNEG1 as the second switch control signal SW2 to the control terminal of the second switch S2 in the active mode.

In an example, the first switch driver 1171 may provide the negative voltage VNEG2 as the first switch control signal SW1 to the control terminal of the first switch S1 in the low power mode, and the second switch driver 1172 may provide the negative voltage VNEG2 as the second switch control signal SW2 to the control terminal of the first switch S2 in the low power mode.

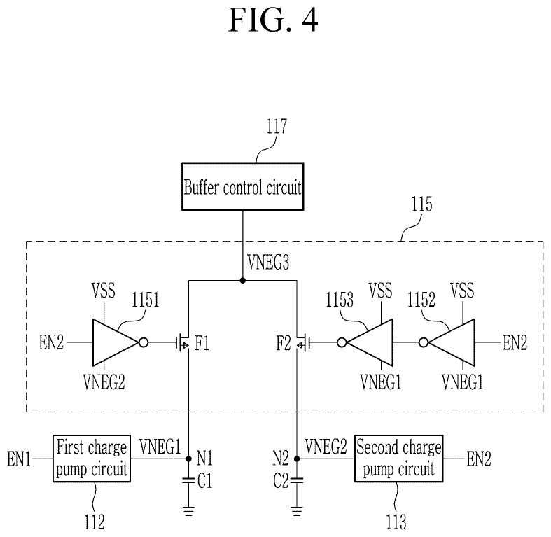

FIG. 4 illustrates an example charge pump selection switch shown in FIG. 3.

Referring to FIG. 4, the charge pump selection switch 115 may include a transistor F1, a transistor F2, an inverter 1151, an inverter 1152, and an inverter 1153.

In an example, the transistor F1 and transistor F2 may be N-type FETs.

A drain of transistor F1 may be connected to the buffer control circuit 117, and a source of transistor F1 may be connected to node N1. The node N1 may represent an output terminal of the first charge pump circuit 112, and the negative voltage VNEG1 output from the first charge pump circuit 112 may be charged in a capacitor C1.

A drain of transistor F2 may be connected to the buffer control circuit 117, and a source of transistor F2 may be connected to node N2. The node N2 may represent an output terminal of the second charge pump circuit 113, and the negative voltage VNEG2 output from the second charge pump circuit 113 may be charged in a capacitor C2.

The inverter 1151 may have an input terminal and an output terminal. The second enable signal EN2 may be input to the input terminal of the inverter 1151, and the output terminal of the inverter 1151 may be connected to the gate of the transistor F1. Accordingly, the transistor F1 may be turned on or turned off in response to the signal output from the inverter 1151.

The inverter 1151 may output a negative voltage VNEG2 when the second enable signal EN2 is at a high level, and output a voltage VSS when the second enable signal EN2 is at a low level. In an example, the voltage VSS may be 0V. That is, since the second enable signal EN2 is at the low level in the active mode, the inverter 1151 may output the voltage VSS to the gate of the transistor F1 in the active mode. Accordingly, the transistor F1 may be turned on, and the negative voltage VNEG1 output from the first charge pump circuit 112 may be provided to the buffer control circuit 117.

In an example, the inverter 1152 may output a negative voltage VNEG1 when the second enable signal EN2 is at the high level, and output a voltage VSS when the second enable signal EN2 is at the low level. The inverter 1153 may output the negative voltage VNEG1 when the output signal of the inverter 1152 is at a high level VSS, and output the voltage VSS when the output signal of the inverter 1152 is at a low level VNEG2.

That is, since the second enable signal EN2 is at low level in the active mode, the inverter 1153 may output the negative voltage VNEG1 to the gate of the transistor F2 in the active mode, and since the second charge pump circuit 113 is in an inactive state, the source of the transistor F2 is in a floating state, and the source voltage of the transistor F2 may become an unspecified voltage, for example, 0V, so the transistor F2 may be turned off.

Additionally, since the second enable signal EN2 is at a high level in the low power mode, the inverter 1151 may output the negative voltage VNEG2 to the gate of the transistor F1 in the low power mode, and the first charge pump circuit 112 is in an inactive state, so the source voltage of the transistor F1 becomes an unspecified voltage, for example, 0V, so the transistor F1 may be turned off.

In an example, in the low power mode, the inverter 1153 may output the positive voltage VSS to the gate of the transistor F2, and the second charge pump circuit 113 is activated, so the negative voltage VNEG2 may be provided to the source of the transistor F2. Accordingly, the source voltage of the transistor F2 becomes the negative voltage VNEG2, so the transistor F2 may turned on, and the negative voltage VNEG2 output from the second charge pump circuit 113 may be provided to the buffer control circuit 117.

Additionally, according to the embodiment, it may be set that the negative voltage VNEG2 is input to a power terminal of the inverter 1151, and a negative voltage VNEG1 is input to the power terminal of the inverter 1153. This is to prevent current from flowing between the gate and drain of the transistor that is turned off. Specifically, in the active mode, the voltage VSS is applied to the gate of the transistor F1 to turn on the transistor F1, and a negative voltage VNEG1 is applied to the gate of the transistor F2 to turn on the transistor F2. At this time, as the transistor F1 is turned on, the drain voltage of the transistor F2 becomes a negative voltage VNEG1, and the gate voltage and drain voltage of the turned-off transistor F2 become the same as the voltage VNEG1, so current may not flow between the gate and drain of transistor F2. Also, in the low power mode, the negative voltage VNEG2 is applied to the gate of transistor F1 to turn off transistor F1, and the voltage VSS is applied to the gate of transistor F2 to turn on transistor F2. At this time, as the transistor F2 is turned on, the drain voltage of the transistor F1 becomes the negative voltage VNEG2, and the gate voltage and drain voltage of the turned-off transistor F1 become the same as the voltage VNEG2, so current may not flow between the gate and drain of transistor F1.

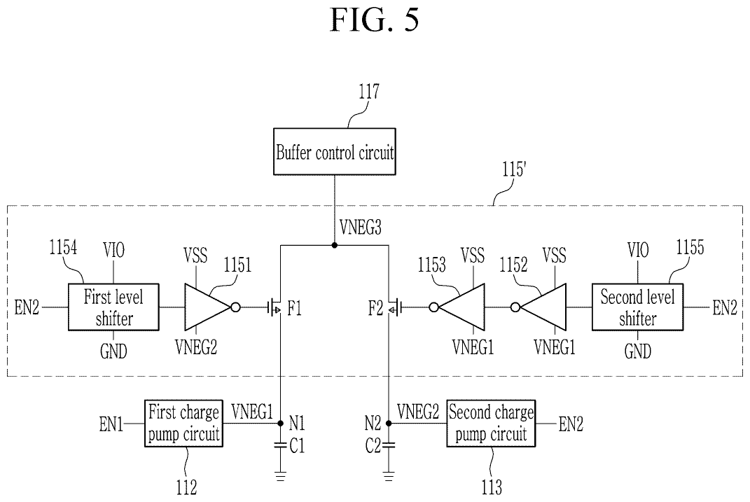

FIG. 5 illustrates another example of the charge pump selection switch shown in FIG. 3.

Referring to FIG. 5, the charge pump selection switch 115′ may further include a first level shifter 1154 and a second level shifter 1155 compared to the charge pump selection switch 115 shown in FIG. 4.

The first level shifter 1154 may change a voltage level of the second enable signal EN2 and provide the changed voltage level of the second enable signal EN2 to the input terminal of the inverter 1151. The first level shifter 1154 may output the voltage VIO to the input terminal of the inverter 1151 in response to the high level of the second enable signal EN2 and output 0V GND to the input terminal of the inverter 1151 in response to the low level of the second enable signal EN2.

The second level shifter 1155 may change a voltage level of the second enable signal EN2 and provide the changed voltage level of the second enable signal EN2 to the input terminal of the inverter 1152. The second level shifter 1155 may output a voltage VIO to the input terminal of the inverter 1152 in response to the high level of the second enable signal EN2 and output 0V GND to the input terminal of the inverter 1152 in response to the low level of the second enable signal EN2.

That is, the first level shifter 1154 and the second level shifter 1155 may change the voltage level in response to the second enable signal EN2 to match the inputs of the inverter 1151 and the inverter 1152, and provide the changed voltage level to the input terminals of the inverter 1151 and the input terminal of the inverter 1152 respectively.

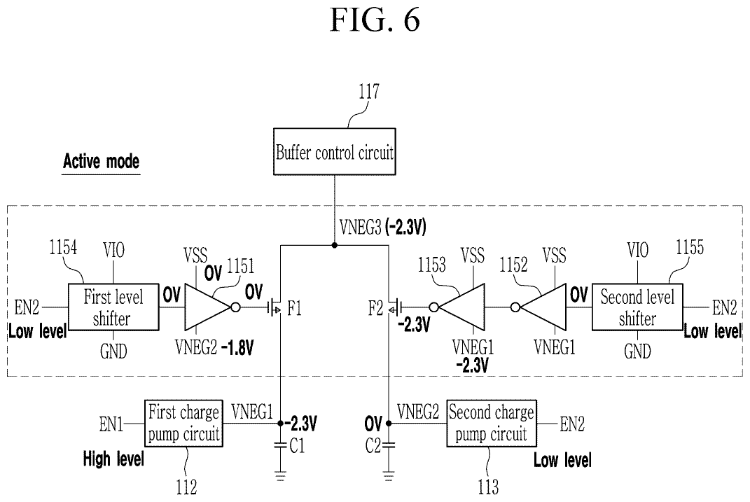

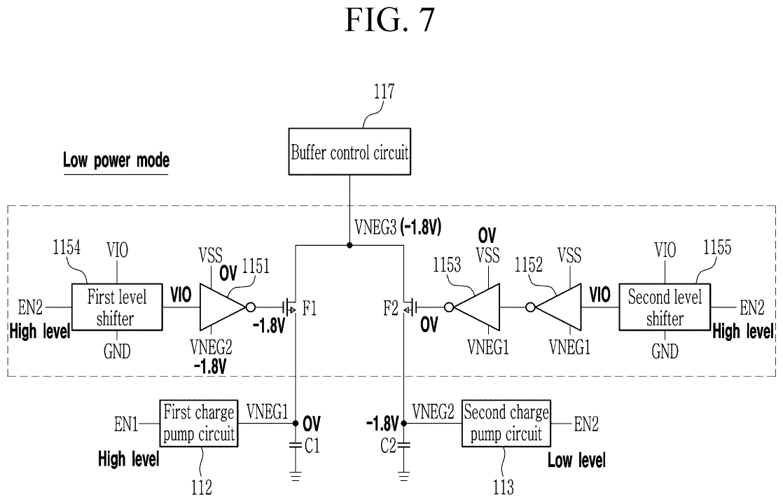

FIGS. 6 and 7 illustrate an operation of the charge pump selection switch shown in FIG. 5 in active mode and low power mode, respectively.

First, depending on the operation mode of the RF switch circuit 100, the first enable signal EN1 and the second enable signal EN2 may be set as shown in Table 1 below.

TABLE 1

| | | Vc | EN1 | EN2 |
|---|---|---|---|---|
| Active mode | Transmitting | 01 | H | L |
| | and receiving | | | |
| | mode | | | |
| | Disable mode | 00 | L | L |

| | | | |
|---|---|---|---|
| Low power mode | 10 | L | H |

In Table 1, the active mode may include a transmission and reception mode and a disable mode, and in the transmission and reception mode, the first enable signal EN1 may have the high level and the second enable signal EN2 may have the low level. In an example, the transmission and reception mode may be a transmission mode for transmitting an RF signal, or a reception mode for receiving an RF signal, or a mode for transmitting and receiving an RF signal. In an example, the disable mode may indicate a disabled state of the RF switch circuit 100, and both the first enable signal EN1 and the second enable signal EN2 may have the low level.

First, referring to Table 1 and FIG. 6, when the operation mode of the RF switch circuit 100 is the active mode, the first enable signal EN1 may be set to the high level, and the second enable signal EN2 may be set to the low level.

According to the second enable signal EN2 having the low level, the second charge pump circuit 113 is in a deactivated (off) state, and the voltage output from the second charge pump circuit 113 may be an unspecified voltage, for example, 0V.

In an example, according to the first enable signal EN1 having the high level, the first charge pump circuit 112 may generate a voltage of −2.3V VNEG1 from the voltage VDD and output the voltage of −2.3V VNEG1. The voltage of −2.3V VNEG1 may be charged to capacitor C1.

In the charge pump selection switch 115, 0V is input to the gate of the transistor F1 according to the second enable signal EN2 having the low level, and the voltage of −2.3V VNEG1 may be input to the gate of the transistor F2. At this time, since the voltage of −2.3V VNEG1 is output from the first charge pump circuit 112, the source voltage of the transistor F1 becomes-2.3V. Therefore, the gate-source voltage of transistor F1 becomes a positive voltage, and transistor F1 may be turned on. In an example, the voltage VNEG2 output from the second charge pump circuit 113 is 0V, and accordingly, the source voltage of the transistor F2 becomes 0V. Therefore, the gate-source voltage of the transistor F2 becomes a negative voltage and the transistor F2 may be turned off.

That is, when the operation mode of the RF switch circuit 100 is the active mode, the transistor F1 of the charge pump selection switch 115 is turned on, and accordingly, the voltage of −2.3V VNEG1 output from the first charge pump circuit 112 may be provided to the buffer control circuit 117.

Next, referring to Table 1 and FIG. 7, when the operation mode of the RF switch circuit 100 is the low power mode, the first enable signal EN1 may be set to the low level, and the second enable signal EN2 may be set to the high level.

According to the first enable signal EN1 having the low level, the first charge pump circuit 112 is in a deactivated (off) state, and the voltage VNEG1 output from the first charge pump circuit 112 may be an unspecified voltage, for example, 0V.

In an example, according to the second enable signal EN2 having the high level, the second charge pump circuit 113 may generate a voltage of −1.8V VNEG2 from the voltage VIO and output the voltage of −1.8V VNEG2. The voltage of −1.8V VNEG2 may be charged to capacitor C2.

In the charge pump selection switch 115, the voltage of −1.8V VNEG2 is input to the gate of the transistor F1 and 0V is input to the gate of the transistor F2 according to the second enable signal EN2 having the high level. At this time, the second charge pump circuit 113 outputs the voltage of −1.8V VNEG2, so the source voltage of the transistor F2 becomes-1.8V. Therefore, the gate-source voltage of the transistor F2 becomes a positive voltage, and the transistor F2 may be turned on. In an example, since the voltage VNEG1 output from the first charge pump circuit 112 is 0V, the source voltage of the transistor F1 becomes 0V, and accordingly, the gate-source voltage of the transistor F1 becomes a negative voltage, and the transistor F1 may be turned off.

That is, when the operation mode of the RF switch circuit 100 is the low power mode, the transistor F2 of the charge pump selection switch 115 is turned on, and accordingly, the voltage of −1.8V VNEG2 output from the second charge pump circuit 113 may be provided to the buffer control circuit 117.

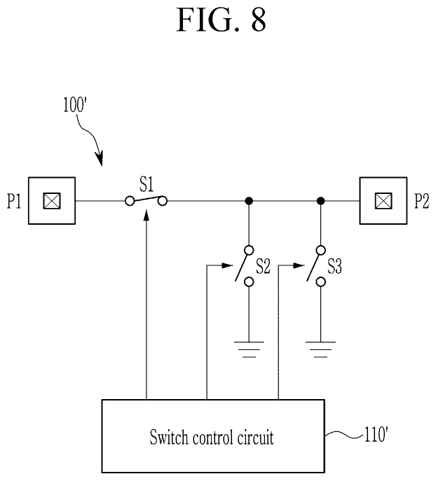

FIG. 8 illustrates an example RF switch circuit, in accordance with one or more embodiments.

Referring to FIG. 8, the RF switch circuit 100′ may further include a third switch S3 compared to the RF switch circuit 100 shown in FIG. 1.

The third switch S3 may be connected between the second port P2 and ground, and may be turned on only in low power mode.

The switch control circuit 110′ may provide a positive voltage VIO as a turn-on voltage to the control terminal of the third switch S3 in the low power mode. At this time, the voltage VIO may be lower than the voltage VDD corresponding to the turn-on voltage of the first switch S1 and the second switch S2.

For example, in the active mode, a voltage of 2.5V VDD may be used as the turn-on voltage of the first switch S1 and the second switch S2, and in the low power mode, a voltage of 1.8V VIO lower than 2.5V may be used as the turn-on voltage of the third switch S3.

In this way, when the third switch S3 is turned on in the low power mode, the impedance of the second port P2, that is, the antenna port, may be matched to 50 ohms, and thus the harmonic characteristics of the second or higher order may be improved.

According to another embodiment, the second switch S2 may also be turned on along with the third switch S3 in the low power mode. In this example, the switch control circuit 110′ may provide the voltage VDD as the turn-on voltage of the second switch S2 in the active mode to the control terminal of the second switch S2, and may provide the voltage VIO as the turn-on voltage of the second switch S2 in the low power mode to the control terminal of the second switch S2.

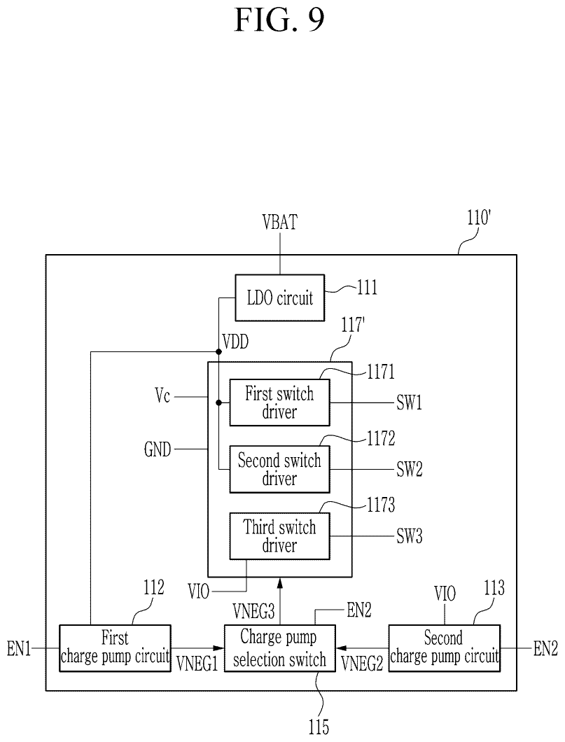

FIG. 9 illustrates an example of the switch control circuit shown in FIG. 8.

Referring to FIG. 9, in the switch control circuit 110′, the buffer control circuit 117′ may further include a third switch driver 1173 compared to the buffer control circuit 117 shown in FIG. 3.

The third switch driver 1173 may generate a third switch control signal SW3 in response to the control signal Vc, and provide the third switch control signal SW3 to the control terminal of the third switch S3.

The third switch driver 1173 may receive positive voltage VIO and the negative voltage VNEG3. The negative voltage VNEG3 may be the voltage VNEG1 in active mode and may be the voltage VNEG2 in low power mode.

The third switch driver 1173 may provide a negative voltage VNEG1 as the third switch control signal SW3 to the control terminal of the third switch S3 in the active mode, and provide a voltage VIO as the third switch control signal SW3 to the control terminal of the third switch in the low power mode.

That is, the third switch S3 may be turned on in response to the voltage VIO in the low power mode.

As described previously, by using the voltage VIO as the turn-on voltage of the third switch S3 in low power mode to turn on the third switch S3, the impedance of the antenna port may be matched to 50 ohms, so the harmonic characteristics of the second or higher order may be improved.

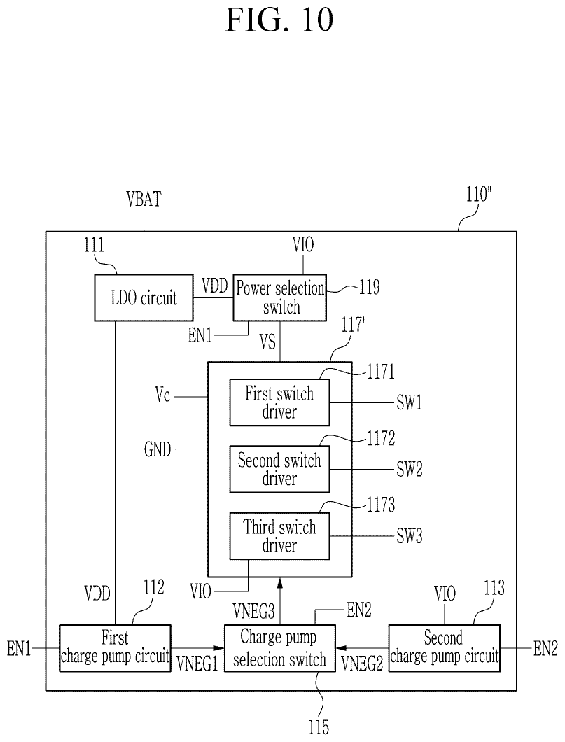

FIG. 10 illustrates another example of the switch control circuit shown in FIG. 8.

Referring to FIG. 10, the switch control circuit 110″ may further include a power source selection switch 119 (or power selection switch) compared to the switch control circuit 110′ shown in FIG. 9.

In the low power mode, the second switch S2 may be turned on together with the third switch S3. At this time, the voltage VIO may be used as the turn-on voltage of the second switch S2. For this purpose, it is necessary to provide the voltage VIO to the second switch driver 1172 in the low power mode.

The power source selection switch 119 may provide different turn-on voltages VS to the buffer control circuit 117 depending on the operation mode of the RF switch circuit 110″. The power source selection switch 119 may select voltage VDD or voltage VIO as the turn-on voltage VS depending on the operation mode of the RF switch circuit 110″.

When the operation mode of the RF switch circuit 110″ is the active mode, the power source selection switch 119 may provide the voltage VDD as the turn-on voltage VS to the buffer control circuit 117. When the operation mode of the RF switch circuit 110″ is the low power mode, the power source selection switch 119 may provide the voltage VIO as the turn-on voltage VS to the buffer control circuit 117.

Accordingly, the power source selection switch 119 may provide the voltage VIO to the buffer control circuit 117 in the low power mode, and the second switch driver 1172 may provide the voltage VIO as the second switch control signal SW2 to the control terminal of the second switch S2, as a result, the second switch S2 may be turned on in a low power mode. At this time, as described in FIG. 9, the third switch driver 1173 may provide the voltage VIO as the third switch control signal SW3 to the control terminal of the third switch S3 in the low power mode, thereby the third switch S3 may be turned on together with the second switch S2.

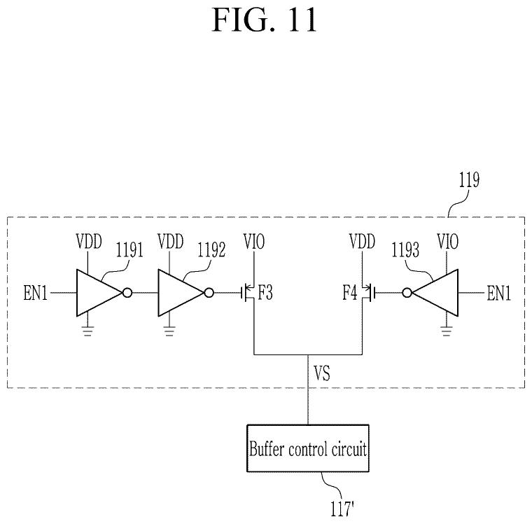

FIG. 11 illustrates an example of the power selection switch 119 shown in FIG. 10.

Referring to FIG. 11, the power source selection switch 119 may include a transistor F3, a transistor F4, an inverter 1191, an inverter 1192, and an inverter 1193.

In an example, the transistor F3 and the transistor F4 may be P-type FETs.

The voltage VIO may be input to a source of the transistor F3, and a drain of the transistor F3 may be an output terminal, and may be connected to the buffer control circuit 117.

The voltage VDD may be input to a source of the transistor F4, and a drain of the transistor F4 may be an output terminal, and may be connected to the buffer control circuit 117.

The inverter 1193 may have an input terminal and an output terminal. The first enable signal EN1 may be input to the input terminal of the inverter 1193, and the output terminal of the inverter 1193 may be connected to the gate of transistor F4. Accordingly, the transistor F4 may be turned on or turned off in response to the signal output from the inverter 1193.

The inverter 1193 may output 0V when the first enable signal EN1 is at the high level, and output the voltage VIO when the first enable signal EN1 is at the low level. That is, since the first enable signal EN1 is at the high level in the active mode, the inverter 1193 may output 0V to the gate of the transistor F4 in the active mode, and a source voltage of the transistor F4 is the voltage VDD, a gate-source voltage of the transistor F4 becomes a negative voltage and thus the transistor F4 may be turned on, and the voltage VS may become the voltage VDD.

In an example, the inverter 1191 may output 0V when the first enable signal EN1 is at the high level, and output voltage VDD when the first enable signal EN1 is at the low level. Additionally, the inverter 1192 may output 0V when the output signal of the inverter 1191 is at a high level VDD, and may output voltage VDD when the output signal of the inverter 1191 is at the low level 0V. That is, since the first enable signal EN1 is at the high level in the active mode, the inverter 1192 may output the voltage VDD to the gate of the transistor F3 in the active mode. At this time, since a source voltage of the transistor F3 is the voltage VIO, a gate-source voltage of the transistor F3 becomes a positive voltage, and thus the transistor F3 may be turned off. Additionally, since the first enable signal EN1 is at the low level in the low power mode, the inverter 1193 may output the voltage VIO to the gate of the transistor F4 in the low power mode. At this time, the source voltage of the transistor F4 is the voltage VDD, but in low power mode, the voltage VDD may be 0V, so the gate-source voltage of the transistor F4 becomes a positive voltage, and so the transistor F4 may be turned off.

Furthermore, since the first enable signal EN1 is at the low level in the low power mode, the inverter 1192 may output 0V to the gate of the transistor F3 in the low power mode. At this time, the source voltage of the transistor F3 is the voltage VIO, so the gate-source voltage of the transistor F3 becomes a negative voltage, and the transistor F3 may be turned on accordingly, and the voltage VS may be voltage VIO.

The voltage VS output from the power source selection switch 119 according to the operation mode may be used as the first switch control signal SW1 and the second switch control signal SW2 in the first switch driver 1171 and the second switch driver 1172, respectively, depending on the operation mode.

According to the embodiment, the voltage VDD may be input to the power terminal of the inverter 1192, and the voltage VIO may be input to the power terminal of the inverter 1193. This is to prevent current from flowing between the gate and drain of the transistor that is turned off. Specifically, in the active mode, the voltage VDD is applied to the gate of the transistor F3 to turn off the transistor F3, and 0V is applied to the gate of the transistor F4 to turn on the transistor F4. At this time, as the transistor F4 is turned on, the drain voltage of the transistor F3 becomes the voltage VDD, and the gate voltage and drain voltage of the turned-off transistor F3 become the same as the voltage VDD, so current may not flow between the gate and drain of transistor F3. Also, in the low power mode, the voltage 0V is applied to the gate of the transistor F3 to turn on the transistor F3, and the voltage VIO is applied to the gate of the transistor F4 to turn off the transistor F4. At this time, as the transistor F3 is turned on, the drain voltage of the transistor F4 becomes the voltage VIO, and the gate voltage and drain voltage of the turned-off transistor F4 become the same as the voltage VIO, so current may not flow between the gate and drain of transistor F4.

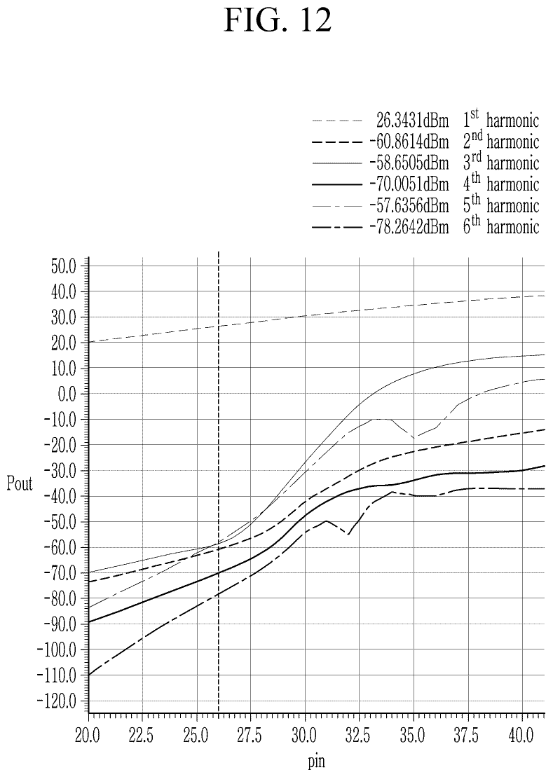

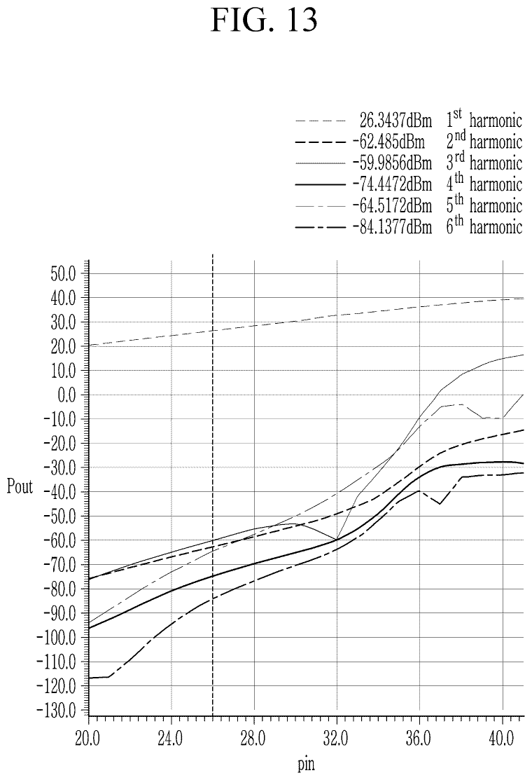

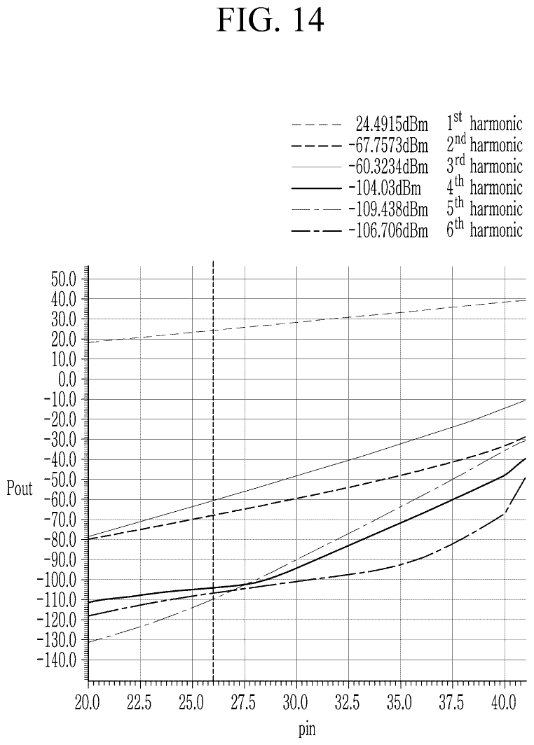

FIGS. 12 to 14 illustrate simulation results of the first to sixth harmonics according to the positive and negative voltages applied to the RF switch circuit, respectively.

First, the simulation conditions were set as shown in Table 2 below, and FIGS. 12, 13, and 14 illustrate the 1^{st} to 6^{th} harmonic characteristics of the power Pout flowing out of the port P2 for the power Pin input to the port P2, that is, antenna port, under the simulation conditions of case 1, case 2, and case 3 set in Table 2, respectively.

TABLE 2

| | Input voltage [V] | | |
|---|---|---|---|
| | VIO | VS | VNEG |
| Example 1 | 1.8 | 0 | 0 |
| Example 2 | 1.8 | 0 | −1.8 |
| Example 3 | 1.8 | 1.8 | −1.8 |

In Table 2, Example 1 is an example in which only the third switch S3 is turned on by the voltage VIO provided by the third switch driver 1173, and the measured results at this time are shown in FIG. 12. Example 2 is an example in which the third switch S3 is turned on by the voltage VIO provided by the third switch driver 1173, and the first switch S1 is turned off by the voltage of −1.8V VNEG2 provided by the first switch driver 1171, and the measured results at this time are shown in FIG. 13. In Example 2, the control terminal of the second switch S2 may be in a floating state. Example 3 is an example in which the third switch S3 is turned on by the voltage VIO provided by the third switch driver 1173, as the voltage VIO is output as the voltage VS from the power source selection switch 119, the second switch S2 is turned on by the voltage VIO provided by the second switch driver 1172, and the first switch S1 is turned off by the voltage of −1.8V VNEG2 provided by the first switch driver 1171, and the measured results at this time are shown in FIG. 14.

The simulation results shown in FIGS. 12 to 14 may be summarized as illustrated in Table 3 below. Table 3 illustrates the second to sixth harmonic characteristics measured at an input power of 26 dBm.

TABLE 3

Harmonic [dBm]

| | 2^{nd} | 3^{rd} | 4^{th} | 5^{th} | 6^{th} |
|---|---|---|---|---|---|
| Example 1 | −60.8 | −58.6 | −70 | −57.6 | −78.2 |
| Example 2 | −62.4 | −59.9 | −74.4 | −64.5 | −84.1 |
| Example 3 | −67.7 | −60.3 | −104 | −109 | −106 |

Referring to FIGS. 12 to 14 and Table 3, it can be seen that the 2^{nd} to 6^{th} harmonic characteristics are improved in case Example 2 compared to Example 1, and the 2^{nd} to 6^{th} harmonic characteristics in Example 3 are improved compared to Example 2.

That is, in the low power mode, turning off the first switch S1 at the voltage of −1.8 V, as in Example 2, may improve the 2^{nd} to 6^{th} harmonic characteristics at the antenna port, compared to when the third switch S3 is turned on, and the first switch S1 and the second switch S2 are turned off at approximately 0V by floating, as in Example 2.

Additionally, turning off the first switch (S1) at a voltage of −1.8 V may improve the 2^{nd} to 6^{th} harmonic characteristics at the antenna port compared to when the first switch (S1) and the second switch (S2) are turned off at approximately 0 V by floating. Additionally, compared to Example 2, turning on the second switch S2 using the voltage VIO in the low power mode as in Example 3 may further improve the 2^{nd} to 6^{th} harmonic characteristics at the antenna port.

According to at least one of the embodiments, harmonic characteristics of the second or higher order at the antenna terminal may be improved in the low power mode.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A switch control circuit that controls a first switch connected between a first port and a second port, and switches a radio frequency (RF) signal, the switch control circuit comprising:
a first charge pump circuit configured to generate, in a first mode, a first negative voltage based on a first voltage;
a second charge pump circuit configured to generate, in a second mode, a second negative voltage higher than the first negative voltage based on a second voltage; and
a first switch driver configured to turn off the first switch in the second mode by providing the second negative voltage to a control terminal of the first switch.

2. The switch control circuit of claim 1, further comprising:
a second switch driver configured to turn on a second switch connected between the second port and ground by providing the second voltage to a control terminal of the second switch in the second mode.

3. The switch control circuit of claim 2, further comprising:
a third switch driver configured to turn on a third switch connected between the second port and the ground by providing the second voltage to a control terminal of the third switch in the second mode.

4. The switch control circuit of claim 3, further comprising:
a charge pump selection switch configured to provide the first negative voltage to the first switch driver, the second switch driver, and third switch driver in the first mode, and configured to provide the second negative voltage to the first driver and the third switch driver in the second mode.

5. The switch control circuit of claim 3, wherein:
the first switch driver is configured to turn on the first switch by providing the first voltage to the control terminal of the first switch in the first mode,
the second switch driver is configured to turn off the second switch by providing the first negative voltage to the control terminal of the second switch in the first mode, and
the third switch driver is configured to turn off the third switch by providing the first negative voltage to the control terminal of the third switch in the first mode.

6. The switch control circuit of claim 5, further comprising:
a power source selection switch configured to provide the first voltage to the first switch driver and the second switch driver in the first mode, and configured to provide the second voltage to the second switch driver in the second mode.

7. The switch control circuit of claim 5, further comprising:
a charge pump selection switch configured to provide the first negative voltage to the first switch driver, the second switch driver, and the third switch driver in the first mode, and configured to provide the second negative voltage to the first switch driver in the second mode.

8. The switch control circuit of claim 1, wherein:
the first mode is an active mode that transmits or receives the RF signal, and the second mode is a low power mode that minimizes power consumption.

9. The switch control circuit of claim 8, wherein:
the active mode comprises at least one of a transmission mode, a reception mode, and a transmission and reception mode, and
the first switch driver is configured to turn on the first switch by providing the first voltage to the control terminal of the first switch, and is configured to turn off the first switch by providing the first negative voltage to the control terminal of the first switch, in the at least one of the transmission mode, the reception mode, and the transmission and reception mode.

10. A radio frequency (RF) switch circuit, comprising:
a first switch connected between a first port and an antenna port;
a second switch connected between the antenna port and ground; and
a switch control circuit configured to control the first switch and the second switch,
wherein the switch control comprises:
a first charge pump circuit configured to generate, in a first mode, a first negative voltage based on a first voltage;
a second charge pump circuit configured to generate, in a second mode, a second negative voltage higher than the first negative voltage based on a second voltage; and
a first switch driver configured to provide the first negative voltage as a turn-off voltage of the first switch in the first mode, and provide the second negative voltage as a turn-off voltage of the first switch in the second mode.

11. The RF switch circuit of claim 10, further comprising:
a third switch connected between the antenna port and the ground, and configured to be turned off in the first mode and turned on in the second mode; and
a third switch driver configured to provide the first negative voltage as a turn-off voltage of the third switch in the first mode, and provide the second voltage as a turn-on voltage of the third switch in the second mode.

12. The RF switch circuit of claim 11, further comprising:
a second switch driver configured to provide the first negative voltage as a turn-off voltage of the second switch in the first mode, and provide the second voltage as a turn-on voltage of the second switch in the second mode.

13. The RF switch circuit of claim 12, further comprising:
a power source selection switch configured to provide the first voltage to the first switch driver and the second switch driver in the first mode, and configured to provide the second voltage to the second switch driver in the second mode.

14. The RF switch circuit of claim 12, further comprising:
a charge pump selection switch configured to provide the first negative voltage to the first switch driver, the second switch driver, and the third switch driver in the first mode, and configured to provide the second negative voltage to the first switch driver and the third switch driver in the second mode.

15. The RF switch circuit of claim 11, further comprising:
a second switch driver configured to provide the first negative voltage as a turn-off voltage of the second switch in the first mode, and float the control terminal of the second switch in the second mode.

16. The RF switch circuit of claim 10, wherein:
the first mode is an active mode that transmits or receives an RF signal through the first switch, and the second mode is a low power mode that minimizes power consumption.
